(19) United States
(12) Patent Application Publication
(10) Pub. No.: US 2007/0195593 A1
(43) Pub. Date: Aug. 23, 2007

(54) STRUCTURE OF MAGNETIC MEMORY CELL AND MAGNETIC MEMORY DEVICE

(75) Inventors: Yuan-Jen Lee, Taipei County (TW); Chien-Chung Hung, Taipei City (TW); Ming-Jer Kao, Tainan City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: INDUSTRIAL TECHNOLOGY RESEARCH INSTITUTE, Hsinchu (TW)

(21) Appl. No.: 11/459,029

(22) Filed: Jul. 21, 2006

(30) Foreign Application Priority Data
Feb. 21, 2006 (TW) 95105723

(51) Int. Cl. G11C 11/14

(52) U.S. Cl. 365/171

(57) ABSTRACT

A structure of magnetic memory cell, suitable for a magnetic memory device with toggle mode access operation is provided, which includes a magnetic pinned stacked layer as a portion of a substrate structure; a tunnel barrier layer disposed on the magnetic pinned stacked layer; a magnetic free stacked layer disposed on the tunnel barrier layer; a magnetic bias stacked layer disposed on the magnetic free stacked layer, wherein the magnetic bias stacked layer applies a compensative magnetic field to the magnetic free stacked layer, so as to move a toggle operation region towards a magnetic zero point. Further, the magnetic field effect of the magnetic bias stacked layer also includes reducing a direct mode region adjacent to the toggle operation region.

### CROSS-REFERENCE TO RELATED APPLICATION

This application claims the priority benefit of Taiwan application serial no. 95105723, filed on Feb. 21, 2006. All disclosure of the Taiwan application is incorporated herein by reference.

### BACKGROUND OF THE INVENTION

1. Field of Invention

The present invention relates to a magnetic memory technique, and more particularly, to a structure of a magnetic memory cell, which operates under a low drive current.

2. Description of Related Art

Magnetic memory, for example, magnetic random access memory (MRAM), is a non-volatile memory with the advantages of non-volatility, high intensity, high read and write speed, and anti-radiation, which is used to record data of 0 or 1 by utilizing magnetic moment of a magnetic substance for adjacent tunnel barrier layers according to the magnetoresistance magnitude generated by the parallel or anti-parallel arrangement. When writing data, the usual method employs two current lines: a bit line (BL) and a write word line (WWL), wherein a magnetic memory cell is selected by the intersection of the induction magnetic fields of the BL and the WWL, and has its magnetoresistance changed by changing the magnetic moment direction of the free layer. When reading the memory data, a current is applied to the selected magnetic memory cell, so that the digital value of memory data is determined from the read magnetoresistance.

FIG. 1 shows the basic structure of a magnetic memory cell. Referring to FIG. 1, when accessing a magnetic memory cell, crossed current lines 100, 102 with proper current are required, which are called, for example, a word line and a bit line according to the operation manner. The two wires generate magnetic fields with two directions after being applied with the current, so as to obtain the magnetic field with desired strength and direction to be applied to the magnetic memory cell 104. The magnetic memory cell 104 is a stacked structure, including a magnetic pinned layer with a fixed magnetic moment in a predetermined direction. The magnitude of magnetoresistance is used for reading data. Further, the data stored in this memory cell can be read out by output electrodes 106, 108. The operation details about the magnetic memory are well-known to those with ordinary skills in the art, and thus will not be further described any more.

FIG. 2 shows the memorizing mechanism of a magnetic memory. In FIG. 2, a magnetic pinned layer 104a has a fixed magnetic moment direction 107. A magnetic free layer 104c is disposed above the magnetic pinned layer 104a, with a barrier layer 104b sandwiched there-between for isolation. The magnetic free layer 104c has a magnetic moment direction 108a or 108b. As the magnetic moment direction 108a is parallel to the magnetic moment direction 107, the magnetoresistance generated represents, for example, the data of 0; otherwise, when the magnetic moment direction 108b is anti-parallel to the magnetic moment direction 107, the magneto-resistance generated represents, for example, the data of 1.

As for a magnetic memory cell, the relationship between the magnetoresistance (R) and the strength of applied magnetic field H is shown in FIG. 3, wherein the solid lines represent magnetoresistance line of a single magnetic memory cell. However, since a magnetic memory device includes a plurality of memory cells, and the strength of the switching field for each memory cell is different, the magnetoresistance lines are changed as shown by the dashed lines, and thereby accessing error occurs. FIG. 4 shows the array structure of a conventional memory cell. The left part of FIG. 4 is an array structure, wherein the memory cell 140 is accessed by, for example, applying magnetic fields with two different directions Hx, Hy. The right part is an Asteroid curve of a free layer. Within the solid-line region, the direction of the magnetic moment for the memory cell 140 does not change due to the small magnetic field. The magnetic field within a limited area outside the solid-line region is suitable for the operation of switching magnetic fields. If the magnetic field is excessively strong, it interferes with the other cells, and is not suitable for use. Therefore, the magnetic field within the operation region 144 is usually used as the operation magnetic field. However, since other memory cells 142 are also sensing with the applied magnetic field, and the operating conditions of the adjacent memory cells 142 are varying, the data stored in memory cells 142 may also be changed due to the applied magnetic field. Therefore, as for the single free layer 104c shown in FIG. 2, accessing errors may occur.

To solve the above-mentioned problems, for example, in the U.S. Pat. No. 6,545,906, a magnetic free stacked layer 166 with a three-layer structure of ferromagnet (FM)/non-magnetic metal (M)/ferromagnet (FM) is used as the free layer instead of the single ferromagnetic material layer, in order to reduce the disturbance between adjacent cells when writing data. As shown in FIG. 5, the ferromagnetic metal layers 150, 154 at top and bottom of the non-magnetic metal layer 152 are arranged anti-parallel to each other to form a closed loop of magnetic field. The magnetic pinned stacked layer 168 below is separated from the magnetic free stacked layer 166 by a tunnel barrier layer (T) 156. The magnetic pinned stacked layer 168 includes a top pinned layer (TP) 158, a non-magnetic metal layer 160, and a bottom pinned layer (BP) 162. The TP layer and the BP layer have fixed magnetic moment. There is also a pinned layer 164, for example an anti-ferromagnetic layer, at the bottom.

As for the magnetic free stacked layer 166 with the three-layer structure, a magnetic anisotropic axis of the magnetic free stacked layer 166 is set to be separated from the bit line BL and the write word line WWL by an angle of 45 degrees, and the direction of the magnetic anisotropic axis is called magnetic easy axis. Thus, the bit line BL and the write word line WWL respectively apply a magnetic field with an angle of 45 degrees relative to the magnetic easy axis to the free stacked layer 166 sequentially, so as to rotate the magnetic moment of the free stacked layer 166. FIG. 6 shows the timing for applying the magnetic field. In FIG. 6, the upper part represents the relative direction between the magnetic easy axis (shown by the double arrow) and the direction of the magnetic field. The lower part is the timing for applying current to the bit line BL and the write word line WWL, wherein the current I_{W} represents that the magnetic field with the positive 45-degree direction relative to the magnetic easy axis is generated, i.e., the vertical axis in the upper part; and the current I_{B} represents that the magnetic field with the negative 45-degree direction relative to the magnetic easy axis is generated, i.e., the horizontal axis in the upper part. According to the timing for applying the current, the magnetic moment directions for the two ferromagnetic layers 150, 154 at top and bottom of the free stacked layer 166 are reversed. The timing for applying the current is achieved by two states, thus, it is also called a toggle mode operation. For each time of the toggle mode operation, the magnetic moment directions for the two ferromagnetic layers 150, 154 at to and bottom of the free stacked layer 166 are reversed once. Since the direction of the magnetic moment for the top pinned layer 158 is fixed, the direction of the magnetic moment for the bottom ferromagnetic layer 154 is parallel or anti-parallel to that of the top pinned layer 158, thus, a binary data is stored.

FIG. 7 shows the reaction of the magnetic moment for the two ferromagnetic layers 150, 154 at top and bottom of the free stacked layer 166 to the strength of the applied magnetic field. FIG. 8 shows a corresponding operation region of the applied magnetic field. Referring to FIG. 7, thin arrows represent the directions of the magnetic moments for the two ferromagnetic layers 150, 154 at to and bottom of the free stacked layer 166. When the applied magnetic field H is weak, the directions of the two magnetic moments are not changed, i.e., the non-switch region 170 in FIG. 8. When the applied magnetic field H is strengthened up to a proper value, the range of the magnetic field is the toggle operation region 174 in the toggle mode. The rotation of the magnetic moment is achieved by magnetic fields with two directions perpendicular to each other according to a certain variation of timing (shown in FIG. 6), so as to rotate the direction of the composite vector that is the magnetic field H. Thus, the magnetic moment is switched stage by stage. However, if the magnetic field H is too strong, the directions of the two magnetic moments are always turned into the same direction as that of the magnetic field H, which is not a suitable operation region (not shown in FIG. 8). Further, there is a direct switch region 172 between the toggle operation region 174 and the non-switch region 170, the direct switch region 172 is also called a direct mode region for short. Since the direct switch region 172 is not easy to be controlled, it is also not suitable for accessing the memory cell.

Although the above-mentioned toggle operation can solve the aforementioned interference problem, it can be seen form FIG. 8 that the current required for entering into the toggle operation region 174 becomes increasingly large. Therefore, in another conventional art as described in U.S. Pat. No. 6,633,498, the toggle operation region 174 of the first quadrant is moved towards the magnetic zero point, so as to reduce the operation current. FIG. 9 shows a schematic view for reducing the operation current in the conventional art. Referring to FIG. 9, the basic structure of the memory cell is still similar to that of FIG. 5. As shown in the left part, the main difference is that the total magnetic moment 180 of the bottom pinned layer 162 is increased relative to the total magnetic moment 182 of the top pinned layer 158. For example, the thickness is increased, so as to increase the value of the total magnetic moment. Since the total magnetic moment of the bottom pinned layer 162 and that of the top pinned layer 158 are imbalanced, a fringe magnetic field is generated, and a compensative field 184 is generated for the free stacked layer 166. The toggle operation region of the first quadrant is moved towards the magnetic zero point, therefore, the operation current for writing is reduced to the critical current 186.

Further discussing about the above operation of FIG. 9, it is found in the present invention that although the toggle operation region is pulled towards the magnetic zero point by applying the compensative field 184, meanwhile the direct operation region is also increased as a result. If the direct operation region exceeds the magnetic zero point, it also causes the operation failure. Therefore, the direct operation region also limits the reducing of operation current. The present invention provides a design to solve these problems, which will be described below.

### SUMMARY OF THE INVENTION

The present invention provides a structure of a magnetic memory cell operated in a toggle mode, which can be used to reduce the range of the direct mode region, so as to reduce the operation current effectively.

The present invention provides a magnetic memory device, wherein a plurality of above-mentioned structures of the magnetic memory cell is used to form a memory array. The magnetic memory device at least has the advantages of high memory density, high operating speed, and low operation current.

The present invention provides a structure of a magnetic memory cell, suitable for a magnetic memory device with toggle mode access operation. The structure of includes a magnetic pinned stacked layer as a portion of a substrate structure; a tunnel barrier layer disposed on the magnetic pinned stacked layer; a magnetic free stacked layer disposed on the tunnel barrier layer; and a magnetic bias stacked layer disposed on the magnetic free stacked layer. Wherein, the magnetic bias stacked layer applies a compensative magnetic field to the magnetic free stacked layer, so as to move a toggle operation region towards a magnetic zero point.

As for the structure of the magnetic memory cell according to an embodiment, the above-mentioned magnetic bias stacked layer is formed by stacking a non-magnetic metal layer, a ferromagnetic metal layer, and an anti-ferromagnetic metal layer. Further, for example, the non-magnetic metal layer is disposed on the magnetic free stacked layer. The ferromagnetic metal layer is disposed on the non-magnetic metal layer. The anti-ferromagnetic metal layer is disposed on the ferromagnetic metal layer.

As for the structure of the magnetic memory cell according to an embodiment, the direction of a magnetic easy axis for the above-mentioned anti-ferromagnetic metal layer is arranged parallel to that of the magnetic free stacked layer.

As for the structure of the magnetic memory cell according to an embodiment, the direction of the magnetic easy axis for the above-mentioned ferromagnetic metal layer is arranged parallel to that of the magnetic free stacked layer.

As for the structure of the magnetic memory cell according to an embodiment, the above-mentioned magnetic free stacked layer is formed by sequentially stacking a bottom ferromagnetic metal layer, a magnetic coupling intermediate layer, and a top ferromagnetic metal layer.

As for the structure of the magnetic memory cell according to an embodiment, the total magnetic moment applied to the magnetic free stacked layer by the above-mentioned magnetic pinned stacked layer is almost zero.

As for the structure of the magnetic memory cell according to an embodiment, in the above-mentioned magnetic free stacked layer, the total magnetic moment of the bottom ferromagnetic metal layer is greater than that of the top ferromagnetic metal layer.

As for the structure of the magnetic memory cell according to an embodiment, the compensative magnetic field generated by the above-mentioned magnetic bias stacked layer has different interaction strength to the bottom ferromagnetic metal layer and the top ferromagnetic metal layer, so as to move the toggle operation region towards the magnetic zero point.

As for the structure of the magnetic memory cell according to an embodiment, the compensative magnetic field generated by the above-mentioned magnetic bias stacked layer includes reducing a direct mode region that is adjacent to the toggle operation region.

The present invention further provides another structure of the magnetic memory cell suitable for a magnetic memory device with toggle mode access operation, which includes a magnetic pinned stacked layer as a portion of a substrate structure; a tunnel barrier layer disposed on the magnetic pinned stacked layer; and a magnetic free stacked layer disposed on the tunnel barrier layer, wherein the magnetic free stacked layer includes a bottom ferromagnetic metal layer, a magnetic coupling intermediate layer, and a top ferromagnetic metal layer. The total magnetic moment of the bottom ferromagnetic metal layer is smaller than that of the top ferromagnetic metal layer.

As for the structure of the magnetic memory cell according to an embodiment, the above-mentioned compensative field further includes reducing a direct mode region that is adjacent to the toggle operation region.

The present invention further provides a magnetic memory device, which uses a plurality of above-mentioned structures of the magnetic memory cells to form a memory array, wherein, the magnetic memory device further includes a circuit structure for accessing one of the magnetic memory cells according to the array arrangement.

Since the present invention further disposes a magnetic bias stacked layer on the magnetic free stacked layer to apply a compensative magnetic field to the magnetic free stacked layer, so as to reduce the direct mode region, the toggle operation region is moved towards the magnetic zero point, thus effectively reducing the operation current. In addition, the direct mode region can be reduced by directly changing the magnitude of the magnetic moment of the magnetic free stacked layer without an external magnetic field.

In order to make the aforementioned and other objects, features and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 shows a basic structure of a magnetic memory cell.

FIG. 2 shows a memorizing mechanism of the magnetic memory.

FIG. 3 shows the relationship between the magnetoresistance (R) of the magnetic memory cell and the strength of the applied magnetic field (H).

FIG. 4 shows an array structure of a conventional memory cell.

FIG. 5 shows a basic structure of the conventional memory cell.

FIG. 6 shows the timing for applying the magnetic field.

FIG. 7 shows the reaction of the magnetic moment direction of the two ferromagnetic layers 150, 154 at top and bottom of the free stacked layer 166 to the applied magnetic field.

FIG. 8 shows a corresponding operation region of the applied magnetic field.

FIG. 9 shows a schematic view of reducing the operation current in the conventional art.

FIG. 10 shows the experiment results of the phenomenon generated in the conventional art.

FIG. 11 shows the operation region below the coordinate of the magnetic field.

FIG. 12 shows the investigation of the reasons for the phenomenon of FIG. 10 according to the present invention.

FIG. 13 shows a schematic cross-sectional view of a structure of a magnetic memory cell according to an embodiment of the present invention.

FIG. 14 shows a schematic view of a compensative mechanism generated by the disposed magnetic bias stacked layer according to an embodiment of the present invention.

FIG. 15 shows the result of an actual simulation of the magnetic memory cell according to an embodiment of the present invention.

FIG. 16 shows a structure of a magnetic memory cell according to another embodiment of the present invention.

FIG. 17 shows the experimental result of an embodiment with the design of FIG. 16 according to an embodiment of the present invention.

### DESCRIPTION OF EMBODIMENTS

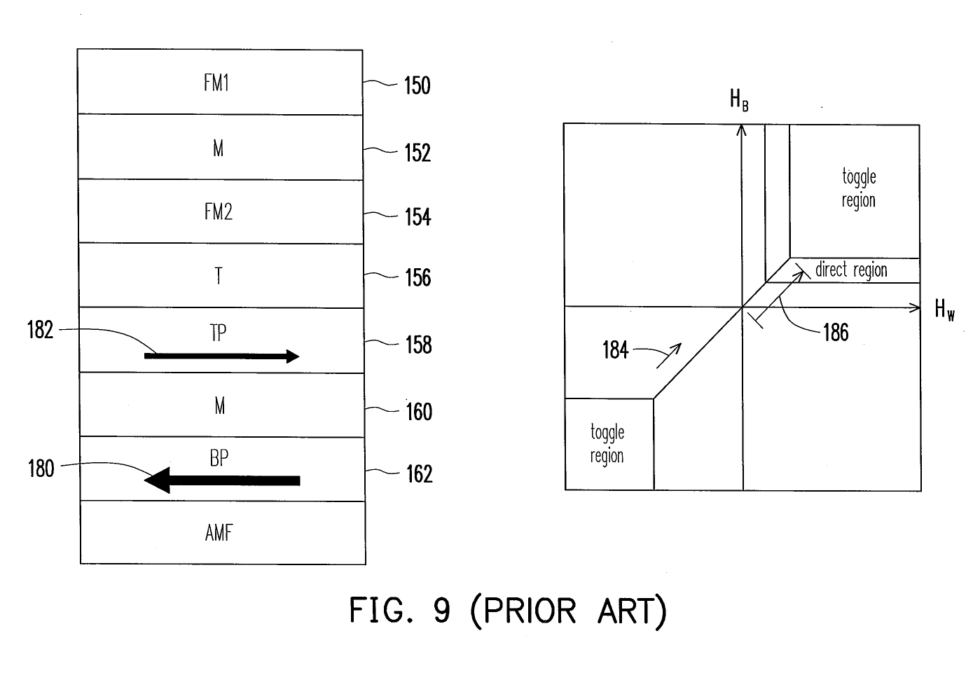

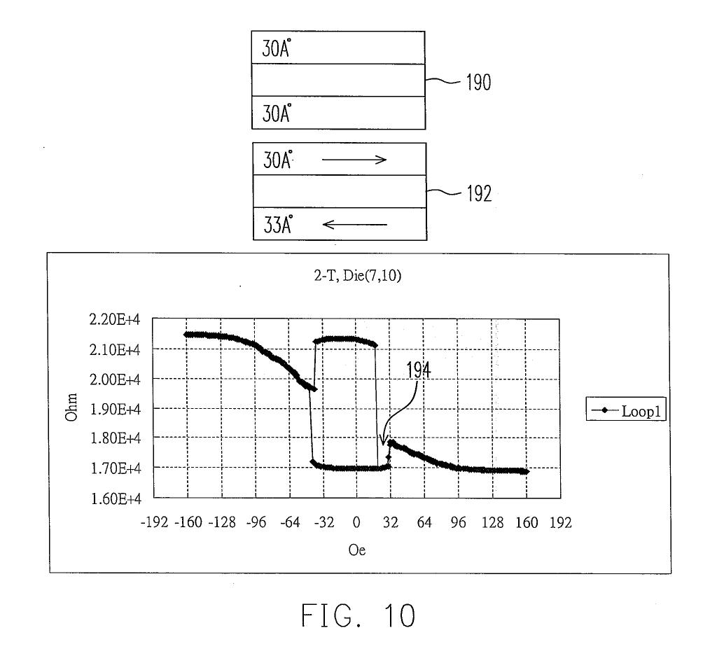

In view of the above, after further researching on the conventional art of FIG. 9, it is found in the present invention that although the toggle operation region is pulled towards the magnetic zero point by applying a compensative field 184, the direct l operation region is also increased, so that the write operation current cannot be further reduced. The further research on the conventional art in the present invention is described below to find out some possible reasons, and thus providing a design for solving the problems. The recited embodiments are used to describe the present invention, and are not intended to limit the scope of the present invention.

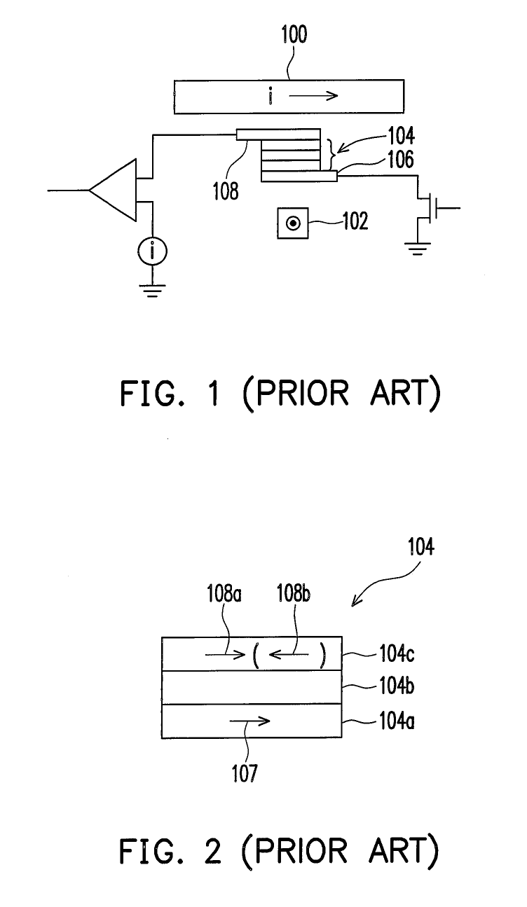

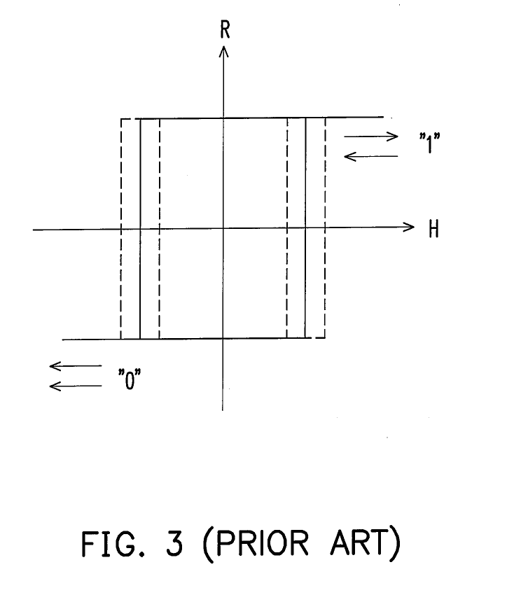

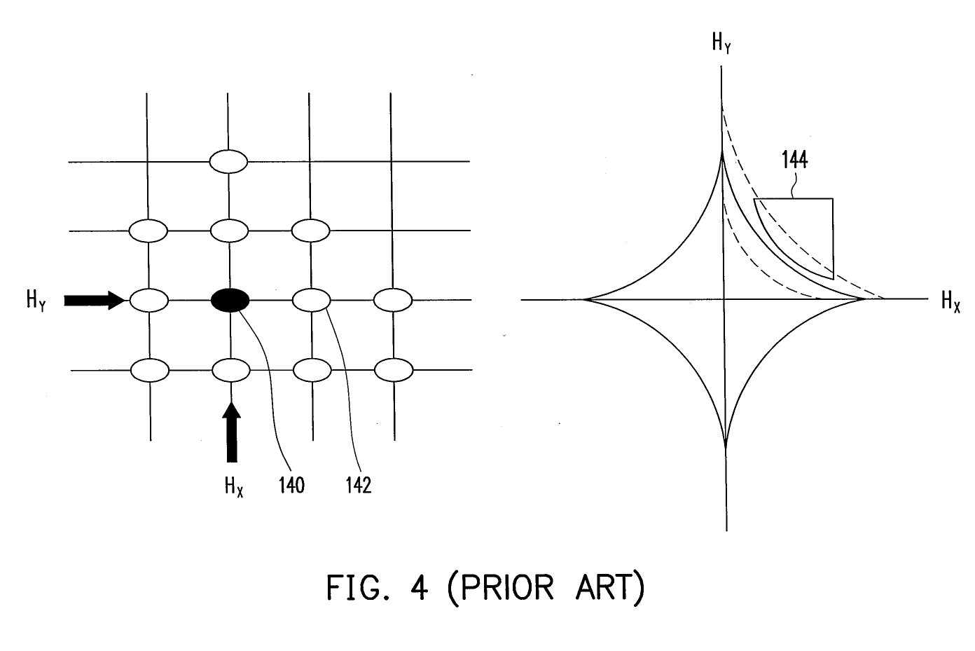

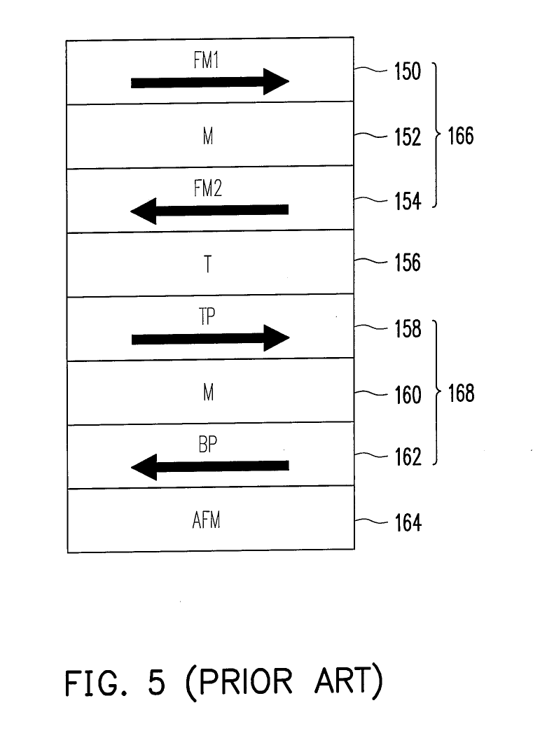

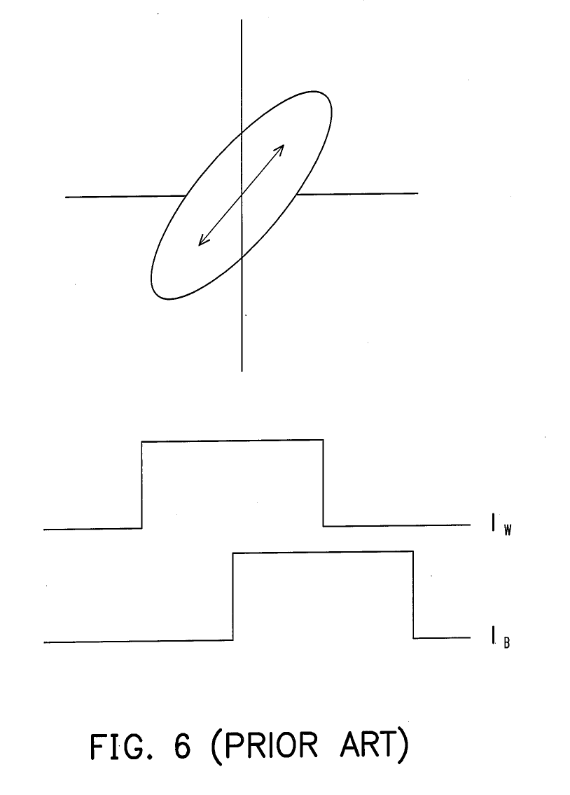

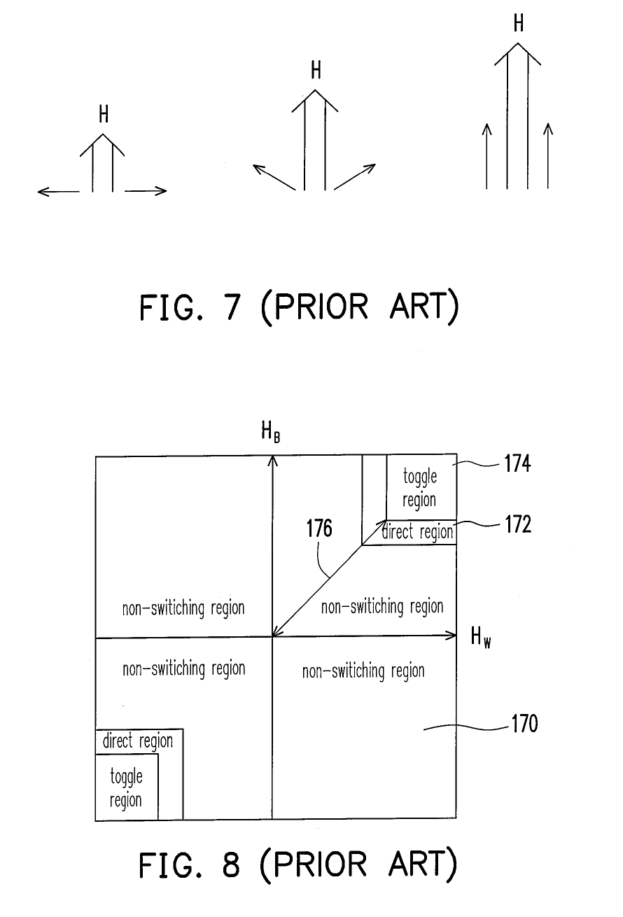

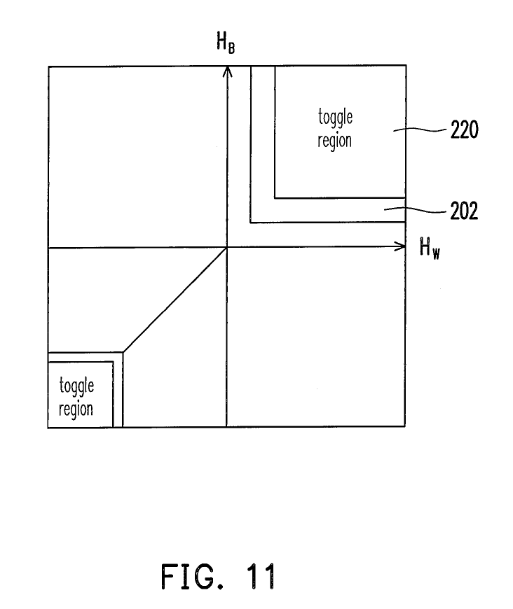

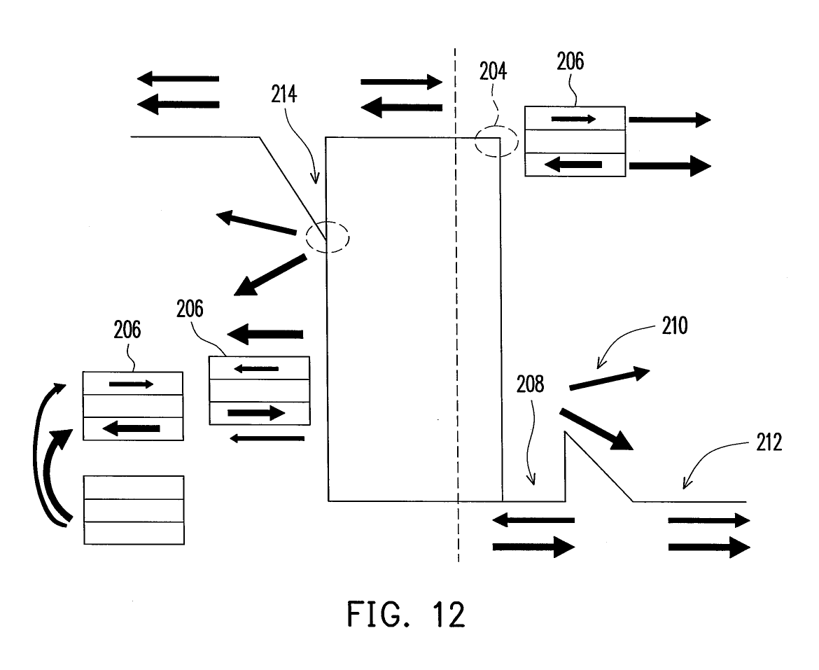

FIG. 10 shows the experiment results of the phenomenon generated in the conventional art. Referring to FIG. 10, the upper part is a schematic view of a conventional structure of a magnetic memory cell, which includes a magnetic pinned stacked layer 192 and a magnetic free stacked layer 190 above the magnetic pinned stacked layer 192. The top and bottom ferromagnetic layers for the magnetic free stacked layer 190 have the same thickness and the same magnetic moment. The bottom pinned layer of the magnetic pinned stacked layer 192 is thicker than the top pinned layer, such that the total magnetic moment of the bottom pinned layer is larger, thereby generating a fringe magnetic field to the magnetic free stacked layer 190. It can be seen from the relationship between the magnetoresistance and the magnetic field in the lower part of FIG. 10. Although the starting point of the toggle operation region on the right has been moved towards the magnetic zero point, it is obvious that a large direct mode region 194 still exists. FIG. 1 shows the operation region below the coordinate of the magnetic field. In FIG. 11, the toggle operation region 220 of the first quadrant is biased towards the magnetic zero point, and meanwhile, the toggle operation region of the third quadrant is also biased along the same direction. FIG. 12 shows the investigation of the reasons for the phenomenon in FIG. 10 according to the present invention. Referring to FIG. 12, it shows the relationship between the magnetoresistance and the magnetic field as seen from an angle of 0 degree. The position marked by the dashed lines is the position of the magnetic field when it is zero, and the direct mode region 208 obviously appears between the toggle operation region 210 and the non-switch region angle 204, whereas the direct mode region is reduced at the region 214. In addition, the magnetic field in the region 212 is excessively strong, thus the magnetic moments of the two ferromagnetic layers at top and bottom of the magnetic free layer 206 are parallel to each other. The function of a conventional magnetic memory cell shown in the lower left part of the figure is further investigated in the present invention, such that a possible explanation is provided as follows. Different magnetic fields are applied to the direct mode region 208 due to the different effects of the magnetic pinned stacked layer on the two ferromagnetic layers at top and bottom of the magnetic free stacked layer 206 caused by different distances. The lower layer being closer to the magnetic field senses a stronger magnetic field. Thus, in the positive magnetic field environment on the right of the dashed line, the direct mode region 208 becomes larger towards the magnetic zero point; whereas, in the negative magnetic field environment on left of the dashed line, the direct mode region is greatly reduced, even disappears.

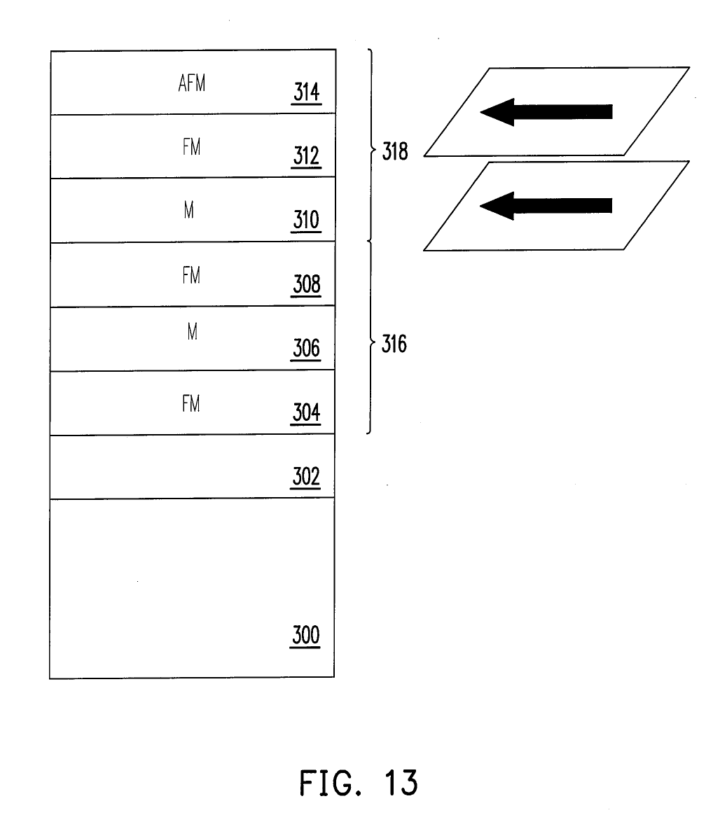

FIG. 13 shows a schematic cross-sectional view of a structure of a magnetic memory cell according to an embodiment of the present invention. The structure of the magnetic memory cell of the present invention can replace the magnetic memory cell 104 of FIG. 1 and form a magnetic memory device with toggle mode access operation together with a circuit structure for accessing the memory cell array. Referring to FIG. 13, the structure of the magnetic memory cell includes a magnetic pinned stacked layer 300, as a portion of the substrate structure; a tunnel barrier layer 302 disposed on the magnetic pinned stacked layer 300; a magnetic free stacked layer 316 disposed on the tunnel barrier layer 302; and a magnetic bias stacked layer 318 disposed on the magnetic free stacked layer 316. The magnetic bias stacked layer 318 applies a compensative magnetic field to the magnetic free stacked layer 316, so as to move a toggle operation region towards a magnetic zero point, and meanwhile, the direct mode region is reduced. Thus, the toggle operation region can further approach to the magnetic zero point. Relatively, the operation current can be reduced effectively. Particularly, the writing operation may be performed with a relatively low current.

The magnetic free stacked layer 316 is, for example, a conventional three-layer structure including a bottom ferromagnetic metal layer 304, a non-magnetic metal layer 308, and a top ferromagnetic metal layer 306. In addition, a magnetic bias stacked layer 318 is further disposed on the magnetic free stacked layer 316 in the present invention. The magnetic bias stacked layer 318 includes, for example, a non-magnetic metal layer 310, a ferromagnetic metal layer 312, and an anti-ferromagnetic metal layer 314. The position relationship between these three layers is that, for example, the non-magnetic metal layer 310 is disposed on the magnetic free structure layer 316; the ferromagnetic metal layer 312 is disposed on the non-magnetic metal layer 310; and the anti-ferromagnetic metal layer 314 is disposed on the ferromagnetic metal layer 312. However, this is not the only way for arranging the layers. For example, the positions of the ferromagnetic metal layer 312 and the anti-ferromagnetic metal layer 314 may be exchanged with each other. Further, the effect of the magnetic bias stacked layer 318 is to generate a compensative field, and apply the compensative field to the magnetic free stacked layer 316. Therefore, the ferromagnetic metal layer 312 and the anti-ferromagnetic metal layer 314 may also be formed by a single ferromagnetic metal layer or a plurality of ferromagnetic metal layers. The anti-ferromagnetic metal layer 314 itself contains magnetic moments of the same magnitude but with different directions, thus the total magnetic moment is zero, which, however, facilitates the fixing of the magnetic moments for the ferromagnetic metal layer 312. The non-magnetic metal layer 310 can be used for isolation, so as to avoid generating too intensive magnetic coupling due to being too close. In other words, the non-magnetic metal layer 310 is not an essential component, that is to say, the structure of the magnetic bias stacked layer 318 only needs to generate a proper compensative field, and a specific structure is not required.

As shown by the arrows, the direction of a magnetic easy axis of the anti-ferromagnetic metal layer 314 is arranged parallel to that of the magnetic free stacked layer 316. Further, the direction of a magnetic easy axis of the ferromagnetic metal layer 312 is also arranged parallel to that of the magnetic free stacked layer. The direction of the magnetic moment for the ferromagnetic metal layer 312 is fixed by the effect of interaction between the ferromagnetic metal layer 312 and the anti-ferromagnetic metal layer 314.

In addition, the magnetic pinned stacked layer 300 has, for example, a usual three-layer structure, and it is adjusted to have the total magnetic moment applied to the magnetic free stacked layer 316 to be zero, for example by adjusting the thickness. The physical phenomenon of a zero total magnetic moment is that the magnetic pinned stacked layer 300 does not generate a conventional fringe magnetic field to influence the magnetic free stacked layer. A bias is applied to the magnetic free stacked layer 316 by the magnetic bias stacked layer 318 in the present invention, such that the toggle operation region is moved towards the magnetic zero point. Further, in order to reduce the direct mode region, the magnetic free stacked layer 316 may be adjusted by the bias effect generated by the magnetic bias stacked layer 318. For example, the magnetic moment of the bottom ferromagnetic metal layer 304 in the magnetic free stacked layer 316 can be adjusted to be larger than the total magnetic moment of the top ferromagnetic metal layer 308. Thus, the distance effect for the magnetic moment of the magnetic bias stacked layer 318 can be reduced or eliminated, and meanwhile, the direct mode region is reduced. The toggle operation region can be much closer to the magnetic zero point, so that the operation current is further reduced.

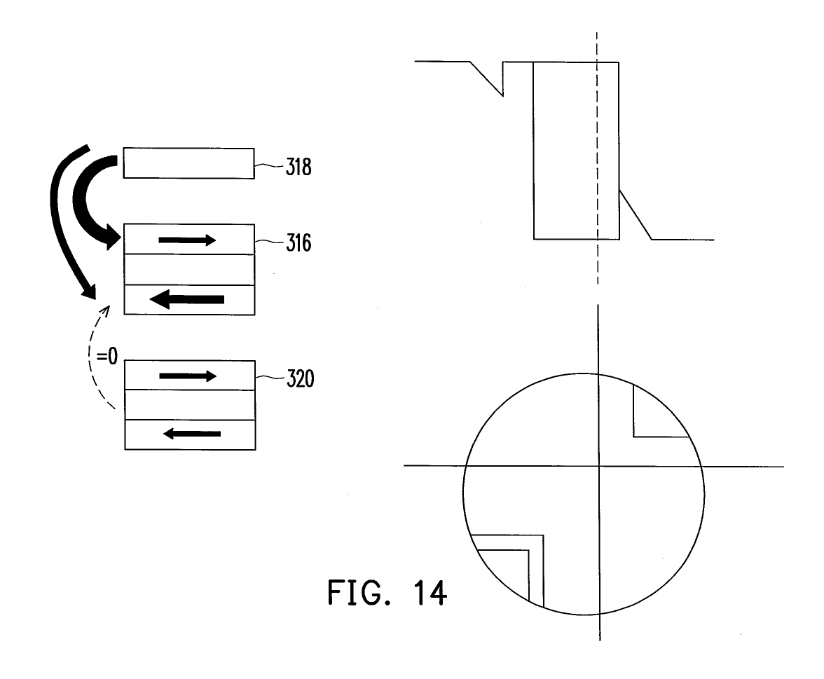

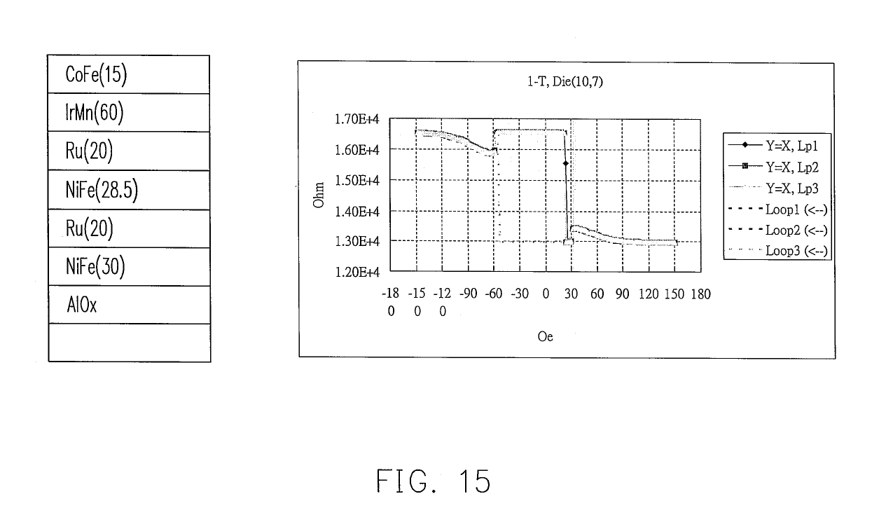

FIG. 14 shows a schematic view of a compensative mechanism generated by the disposed magnetic bias stacked layer according to an embodiment of the present invention. Referring to FIG. 14, the magnetic moment of the two ferromagnetic metal layers at top and bottom of the magnetic free stacked layer 316 are properly adjusted, so as to counteract the different effects generated by the magnetic bias stacked layer 318 to the magnetic free stacked layer 316 due to different distances. The result is shown in the right part of the figure. Obviously, the toggle operation region in the first quadrant is biased towards the magnetic zero point (the point-line position). Meanwhile, the direct mode region in the first quadrant is also eliminated effectively.

The material of the non-ferromagnetic metal layer 310 for the above-mentioned magnetic bias stacked layer 318 is, for example, Cu, Ru, Ag, or another conductive metal. The material of the ferromagnetic metal layer 312 is, for example, Fe, Co, Ni, CoFe, CoFeB, or another ferromagnetic metal. The material of the anti-ferromagnetic metal layer 314 is, for example, RtMn, MnIr, CoO, or another anti-ferromagnetic metal. The material of the tunnel barrier layer 302 is, for example, aluminum oxide. The manufacture of the magnetic bias stacked layer 318 is further added in the present invention, the process of which is compatible with the conventional process, and can be achieved easily without any difficulties in the manufacturing process.

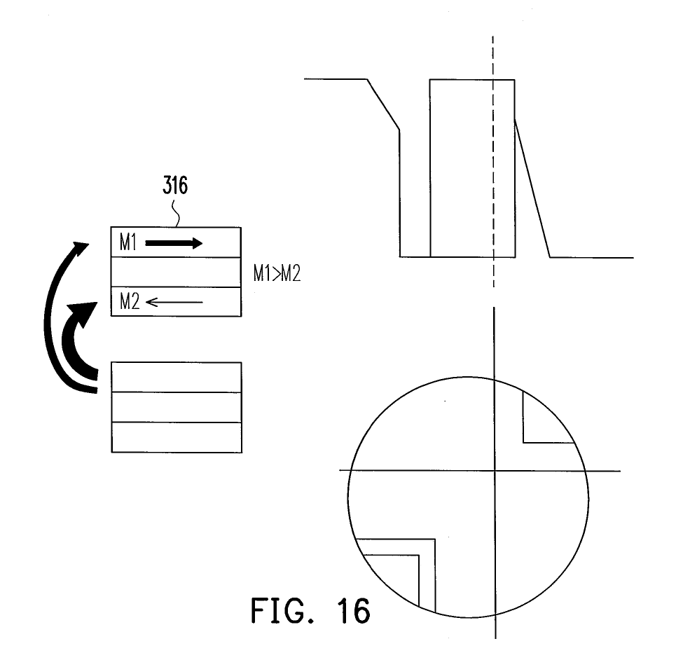

FIG. 15 shows the result of an actual experiment of the magnetic memory cell according to an embodiment of the present invention. Referring to FIG. 15, the material of six layers on the tunnel barrier layer AlOₓ is as shown in the left part of the figure. In addition, the material of each layer is NiFe, Ru, NiFe, Ru, IrMn, CoFe in sequence. The thickness of each layer is, for example, 30, 20, 28.5, 20, 60, 15 in sequence with the unit of angstroms (=10⁻⁸ cm). As can be seen from the experiment result of the right part of the figure, the toggle operation region is biased towards the magnetic zero point, and there are almost no direct mode regions. Therefore, the memory cell structure provided in the present invention indeed achieves the objective of the present invention.

Further, in view of the same consideration, the present invention further provides a modified design. FIG. 16 shows a structure of a magnetic memory cell according to another embodiment of the present invention. Referring to FIG. 16, in order to reduce the direct mode region and to cause the toggle region towards the magnetic zero point, the present invention proposes that it may just need to adjust the magnetic free stacked layer. As the direct mode region occurs due to the different effects on the two ferromagnetic metal layers at top and bottom of the magnetic free stacked layer generated by the magnetic pinned stacked layer, the total magnetic moment of the two ferromagnetic metal layers at top and bottom of the magnetic free stacked layer also can be adjusted without adding the magnetic bias stacked layer. In the left part of the figure, the total magnetic moment ml of the top ferromagnetic metal layer is greater than the total magnetic moment m₂ of the bottom ferromagnetic metal layer (m₁>m₂) for example by adjusting the thickness. As a result, the effect on the bottom ferromagnetic metal layer by the magnetic pinned stacked layer is greater than the effect on the top ferromagnetic metal layer. However, with the condition of m₁>m₂, the difference caused by the magnetic pinned stacked layer can be balanced. The result is shown in the right part of the figure that, the toggle operation region in the first quadrant is also X biased towards the magnetic zero point, and there are almost no direct mode regions.

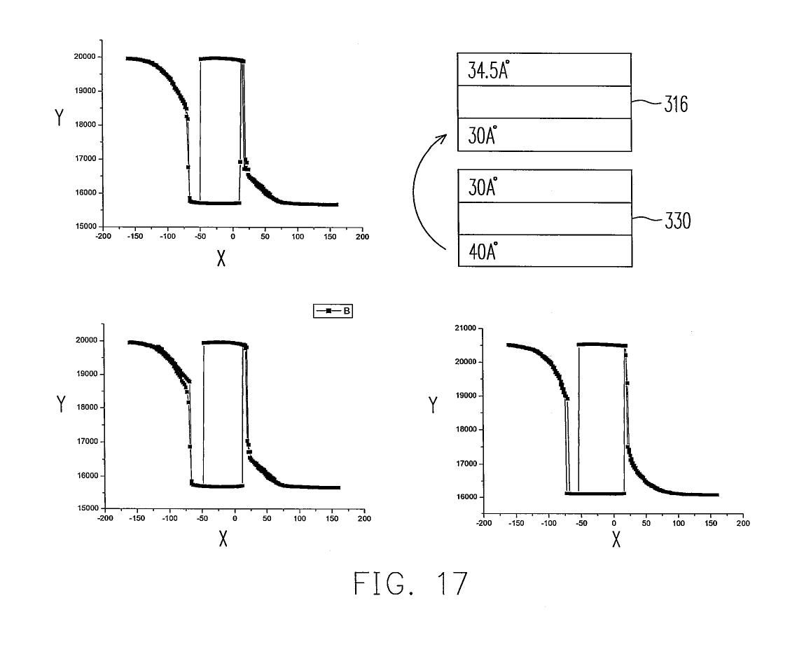

FIG. 17 shows the experiment results for an example of the design of FIG. 16 according to an embodiment of the present invention. Referring to FIG. 17, the thickness of the two layers at top and bottom of the magnetic pinned stacked layer 330 is respectively set to be, for example, 30 angstroms and 40 angstroms, so as to generate a fringe magnetic field. The thickness of the two layers at top and bottom of the magnetic free stacked layer 316 is respectively set to be, for example, 34.5 angstroms and 30 angstroms. The other three drawings show the several experiment results. As can be seen from the experiment results that, the design of this embodiment can also achieve a similar effect.

In summary, after researching and appreciating some factors for influencing the direct mode region in details, the present invention provides a design as shown in FIGS. 13 and 16. The direct mode region is effectively reduced by manufacturing the magnetic bias stacked layer 318 or adjusting the magnetic moment of the magnetic free stacked layer 316, and thereby reducing the operation current.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A structure of a magnetic memory cell, suitable for a magnetic memory device with toggle mode access operation, comprising:
a magnetic pinned stacked layer, as a portion of a substrate structure;
a tunnel barrier layer, disposed over the magnetic pinned stacked layer;
a magnetic free stacked layer, disposed over the tunnel barrier layer; and
a magnetic bias stacked layer, disposed over the magnetic free stacked layer,
wherein the magnetic bias stacked layer applies a compensative magnetic field to the magnetic free stacked layer, so as to move a toggle operation region towards a magnetic zero point.

2. The structure of a magnetic memory cell as claimed in claim 1, wherein the magnetic bias stacked layer is formed by stacking a non-magnetic metal layer, a ferromagnetic metal layer, and an anti-ferromagnetic metal layer.

3. The structure of a magnetic memory cell as claimed in claim 2, wherein the non-magnetic metal layer is disposed on the magnetic free stacked layer; and the ferromagnetic metal layer and the anti-ferromagnetic metal layer are stacked on the non-magnetic metal layer in sequence or in reversed sequence.

4. The structure of a magnetic memory cell as claimed in claim 2, wherein the direction of a magnetic easy axis of the anti-ferromagnetic metal layer is arranged parallel to that of the magnetic free stacked layer.

5. The structure of a magnetic memory cell as claimed in claim 2, wherein the direction of a magnetic easy axis of the ferromagnetic metal layer is arranged parallel to that of the magnetic free stacked layer.

6. The structure of a magnetic memory cell as claimed in claim 2, wherein the direction of a magnetic moment of the ferromagnetic metal layer is fixed by an effect of interaction of the ferromagnetic metal layer with the anti-ferromagnetic metal layer.

7. The structure of a magnetic memory cell as claimed in claim 2, wherein the magnetic free stacked layer is formed by stacking a bottom ferromagnetic metal layer, a magnetic coupling intermediate layer, and a top ferromagnetic metal layer in sequence.

8. The structure of a magnetic memory cell as claimed in claim 7, wherein a total magnetic moment applied to the magnetic free stacked layer by the magnetic pinned stacked layer is zero.

9. The structure of a magnetic memory cell as claimed in claim 8, wherein in the magnetic free stacked layer, a total magnetic moment of the bottom ferromagnetic metal layer is greater than that of the top ferromagnetic metal layer.

10. The structure of a magnetic memory cell as claimed in claim 9, wherein the compensative magnetic field generated by the magnetic bias stacked layer has different effects on the bottom ferromagnetic metal layer and the top ferromagnetic metal layer, so as to move the toggle operation region towards the magnetic zero point.

11. The structure of a magnetic memory cell as claimed in claim 1, wherein the compensative magnetic field generated by the magnetic bias stacked layer causes reducing a direct mode region adjacent to the toggle operation region.

12. A structure of a magnetic memory cell, suitable for a magnetic memory device with toggle mode access operation, comprising:
a magnetic pinned stacked layer, as a portion of a substrate structure;
a tunnel barrier layer, disposed over the magnetic pinned stacked layer; and
a magnetic free stacked layer, disposed over the tunnel barrier layer, wherein the magnetic free stacked layer includes a bottom ferromagnetic metal layer, a magnetic coupling intermediate layer, and a top ferromagnetic metal layer,
wherein a total magnetic moment of the bottom ferromagnetic metal layer is smaller than that of the top ferromagnetic metal layer; an effect on the bottom ferromagnetic metal layer by the magnetic pinned stacked layer is greater than an effect on the top ferromagnetic metal layer, so as to generate a compensative field to a toggle operation region and thereby cause the toggle operation region towards a magnetic zero point.

13. The structure of a magnetic memory cell as claimed in claim 12, wherein the compensative field further causes a reduction of a direct mode region adjacent to the toggle operation region.

14. A magnetic memory device with toggle mode access operation, comprising:
a plurality of magnetic memory cells, arranged in an array; and
a circuit structure, for accessing one of the magnetic memory cells-according to the array arrangement,
wherein each of the magnetic memory cells comprises:
a magnetic pinned stacked layer, as a portion of a substrate structure;
a tunnel barrier layer, disposed over the magnetic pinned stacked layer;
a magnetic free stacked layer, disposed over the tunnel barrier layer; and
a magnetic bias stacked layer, disposed over the magnetic free stacked layer, wherein the magnetic bias stacked layer applies a compensative magnetic field to the magnetic free stacked layer, so as to move a toggle operation region towards a magnetic zero point.

15. The magnetic memory device as claimed in claim 14, wherein the magnetic bias stacked layer is formed by stacking a non-magnetic metal layer, a ferromagnetic metal layer, and an anti-ferromagnetic metal layer.

16. The magnetic memory device as claimed in claim 15, wherein the non-magnetic metal layer is disposed on the magnetic free structure layer; and the ferromagnetic metal layer and the anti-ferromagnetic metal layer are stacked on the non-magnetic metal layer in sequence or in reversed sequence.

17. The magnetic memory device as claimed in claim 15, wherein the direction of a magnetic easy axis of the anti-ferromagnetic metal layer is arranged parallel to that of the magnetic free stacked layer; and the direction of a magnetic easy axis of the ferromagnetic metal layer is arranged parallel to that of the magnetic free stacked layer.

18. The magnetic memory device as claimed in claim 15, wherein the direction of a magnetic easy axis of the ferromagnetic metal layer is fixed by an effect of interaction of the ferromagnetic metal layer with the anti-ferromagnetic metal layer.

19. The magnetic memory device as claimed in claim 15, wherein the magnetic free stacked layer is formed by stacking a bottom ferromagnetic metal layer, a non-magnetic metal layer, and a top ferromagnetic metal layer in sequence.

20. The magnetic memory device as claimed in claim 14, wherein a total magnetic moment applied to the magnetic free stacked layer by the magnetic pinned stacked layer is zero.

21. The magnetic memory device as claimed in claim 14, wherein the compensative magnetic field generated by the magnetic bias stacked layer causes reducing a direct mode region adjacent to the toggle operation region.

22. A magnetic memory device with toggle mode access operation, comprising:
a plurality of magnetic memory cells, arranged in an array; and
a circuit structure, for accessing one of the magnetic memory cells according to the array arrangement,
wherein each of the magnetic memory cells comprises:
a magnetic pinned stacked layer, as a portion of a substrate structure;
a tunnel barrier layer, disposed over the magnetic pinned stacked layer; and
a magnetic free stacked layer, disposed over the tunnel barrier layer, wherein the magnetic free stacked layer includes a bottom ferromagnetic metal layer, a magnetic coupling intermediate layer, and a top ferromagnetic metal layer,
wherein a magnetic moment of the bottom ferromagnetic metal layer is smaller than that of the top ferromagnetic metal layer, and an effect on the bottom ferromagnetic metal layer by the magnetic pinned stacked layer is greater than an effect on the top ferromagnetic metal layer, so as to generate a compensative field to a toggle operation region and thereby cause the toggle operation region towards a magnetic zero point.

23. The magnetic memory device as claimed in claim 22, wherein the compensative field further causes reducing a direct mode region adjacent to the toggle operation region.
